(19) United States
(12) Patent Application Publication
(10) Pub. No.: US 2025/0366294 A1
(43) Pub. Date: Nov. 27, 2025

(54) PACKAGING STRUCTURE AND FORMATION METHOD THEREOF

(71) Applicant: Lextar Electronics Corporation, Hsinchu City (TW)

(72) Inventors: Shiou-Yi KUO, Hsinchu City (TW); Jing-Kai CHIU, Hsinchu City (TW); Tsung-Hao SU, Hsinchu City (TW); Wei-Yuan MA, Hsinchu City (TW)

(21) Appl. No.: 19/191,985

(22) Filed: Apr. 28, 2025

(30) Foreign Application Priority Data
May 23, 2024 (TW) 113119058

(51) Int. Cl. H10H 29/85; H01L 25/075; H10H 29/01; H10H 29/14; H10H 29/80; H10H 29/854

(52) U.S. Cl. CPC H10H 29/8506; H01L 25/0753; H10H 29/032; H10H 29/0362; H10H 29/0364; H10H 29/14; H10H 29/832; H10H 29/854; H10H 29/857

(57) ABSTRACT

A packaging structure and a formation method thereof are provided. The packaging structure includes a base, a semiconductor element, a wrap layer, a cap layer, and an electrical connecting structure. The wrap layer is disposed on the base, covers the semiconductor element, and exposes the top surface of the semiconductor element. The cap layer is disposed on the wrap layer and the semiconductor element and includes a first and a second part. The first part is in contact with the semiconductor element. The second part is in contact with the wrap layer, wherein in measurement results of Fourier transform infrared spectroscopy, the ratio between maximum intensities at wavenumbers of 1060 cm⁻¹ to 1080 cm⁻¹ and 780 cm⁻¹ to 800 cm⁻¹ of the second part is greater than 0.65. The electrical connecting structure passes through the base and the wrap layer to electrically connect to the semiconductor element.

### CROSS REFERENCE TO RELATED APPLICATIONS

This application claims priority of Taiwan Patent Application No. 113119058, filed on May 23, 2024, and the content of the entirety of which is incorporated by reference herein.

### BACKGROUND OF THE DISCLOSURE

### Field of the Disclosure

The present disclosure relates to semiconductor technology and, in particular, to a packaging structure and a formation method thereof.

### Description of the Related Art

As the size of semiconductor elements is gradually scaled down, the number of semiconductor elements in the packaging structure increases rapidly, which poses a serious challenge to the manufacturing process. To deal with the numerous semiconductor elements, a mass transfer process is commonly used to transfer these semiconductor elements from the growth substrate to the carrier, or from the carrier to the circuit board, so that the semiconductor elements can be processed more easily. Although existing packaging structures have largely met their intended purposes, they do not meet requirements in all respects. Therefore, some problems still need to be overcome regarding packaging structures and the formation methods thereof.

### BRIEF SUMMARY OF THE DISCLOSURE

In some embodiments of the present disclosure, a packaging structure is provided. The packaging structure includes a base, a semiconductor element, a wrap layer, a cap layer, and an electrical connecting structure. The base has a first side and a second side opposite to each other. The semiconductor element is disposed on the first side of the base. The wrap layer is disposed on the first side of the base. The wrap layer covers the semiconductor element and exposes the top surface of the semiconductor element. The cap layer is disposed on the wrap layer and the semiconductor component and includes a first part and a second part. The first part coves and is in contact with the top surface of the semiconductor element. The second part covers and is in contact with the wrap layer, wherein in measurement results of Fourier transform infrared spectroscopy, the ratio between a maximum intensity of the second part at a wavenumber of 1060 cm⁻¹ to a wavenumber of 1080 cm⁻¹ and a maximum intensity of the second part at a wavenumber of 780 cm⁻¹ to a wavenumber of 800 cm⁻¹ is greater than 0.65. The electrical connecting structure is disposed on the second side of the base and passes through the base and the wrap layer to electrically connect to the semiconductor element.

In some embodiments of the present disclosure, a formation method of a packaging structure is provided. The formation method of the packaging structure includes the following steps: a cap layer is provided; a semiconductor element is disposed on the cap layer, and a top surface of the semiconductor element covers a portion of the cap layer; a surface treatment process is performed on the semiconductor element and the portion of the cap layer not covered by the semiconductor element; a wrap layer is disposed on the semiconductor element and the cap layer; a connecting portion is disposed in the wrap layer, and the connecting portion is electrically connected to the semiconductor element; a base is disposed on the wrap layer; a bonding pad is disposed on the base, and the bonding pad is electrically connected to the connecting portion.

The packaging structure and the formation method thereof of the present disclosure can be applied in a variety of electrical devices. In order to make the features and advantages of the present disclosure more comprehensible, various embodiments are specially cited below, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 3 are cross-sectional views showing the packaging structure at different stages of the formation method according to some embodiments of the present disclosure.

FIG. 4 shows a measurement result of Fourier-transform infrared spectroscopy (FTIR) of different parts of the cap layer according to some embodiments of the present disclosure.

FIGS. 5 to 10 are cross-sectional views showing the packaging structure at different stages of the formation method according to some embodiments of the present disclosure.

### DETAILED DESCRIPTION OF THE DISCLOSURE

The following disclosure provides many different embodiments or examples for implementing the various features of the present disclosure. Specific examples of features and their configurations are described below to simplify the embodiments of the present disclosure, but certainly not to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In some embodiments of the present disclosure, terms about disposing and connecting, such as “disposing”, “connecting” and similar terms, unless otherwise specified, may refer to two features are in direct contact with each other, or may also refer to two features are not in direct contact with each other, wherein there is an additional connect feature between the two features. The terms about disposing and connecting may also include the case where both features are movable, or both features are fixed.

In addition, ordinal numbers such as “first”, “second”, and the like used in the specification and claims are configured to modify different features or to distinguish different embodiments or ranges, rather than to limit the number, the upper or lower limits of features, and are not intended to limit the order of manufacture or arrangement of features.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meaning as commonly understood by one of ordinary skill in the art. It should be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

It should be understood that, for clarity of explanation, some elements of the device are omitted in the drawings, and only some elements are schematically illustrated. In some embodiments, additional components may be added to the devices described below. In other embodiments, some components of the device described below may be replaced or omitted. It should be understood that, in some embodiments, additional operational steps may be provided before, during, and/or after the formation method of the device. In some embodiments, some of the steps described may be replaced or omitted, and the order of some of the steps described is interchangeable.

The present disclosure retains the catch material as a carrier that is used in the transfer process, so as to omit the molding step, the flipping step, and the debonding step after the component is transferred. In this way, the packaging structure of the present disclosure can greatly simplify the manufacturing process and has the benefit effects of fewer formation steps and low cost.

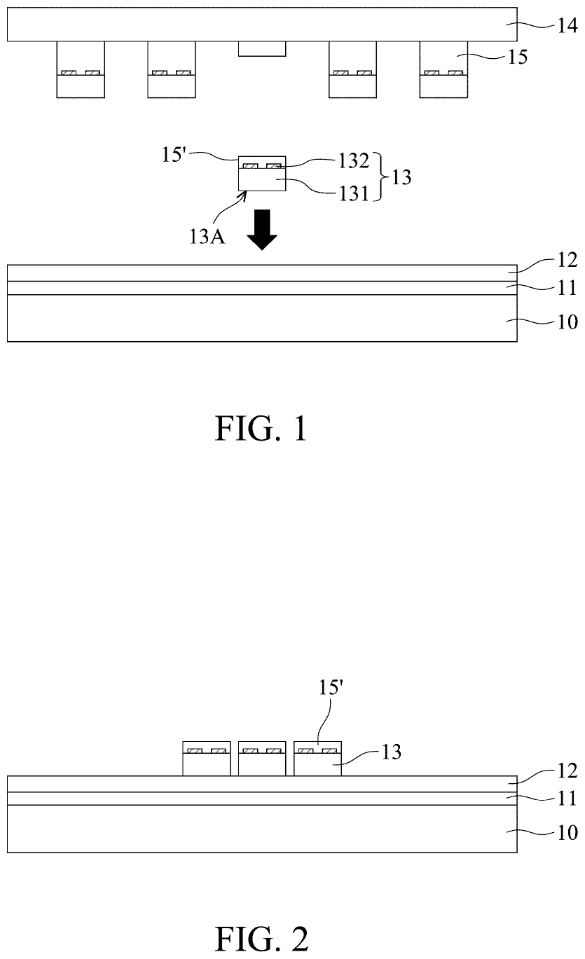

FIGS. 1 to 3 and FIGS. 5 to 10 are cross-sectional views showing the packaging structure at different stages of the formation method according to some embodiments of the present disclosure. To simplify the drawings, only a single packaging structure 1 is shown in some drawings to facilitate clear explanation. In other embodiments, there may be a plurality of packaging structures 1. For example, the packaging structures 1 may be two, three, four, or more, and may be arranged in an array.

As shown in FIG. 1, the carrier 10 is provided for carrying components (e.g., the semiconductor element 13) thereon. In some embodiments, the carrier 10 may include conductive materials or non-conductive materials. For example, the conductive material may include silicon (Si), silicon carbide (SiC), gallium nitride (GaN), aluminum gallium nitride (AlGaN), aluminum nitride (AlN), gallium phosphide (GaP), gallium arsenide (GaAs), aluminum gallium arsenide (AlGaAs), other suitable materials, or a combination thereof, but the present disclosure is not limited thereto. The non-conductive material may include glass, quartz, sapphire, diamond (C), ceramic, polyimide (PI), polycarbonate (PC), polyethylene terephthalate (PET), polypropylene (PP), other suitable materials, or a combination thereof, but the present disclosure is not limited thereto.

As shown in FIG. 1, following the above steps, the adhesive layer 11 is disposed on the carrier 10, which is used to bond the carrier 10 and the catch material (hereinafter, represented by the “cap layer 12”). In some embodiments, the adhesive layer 11 may be a release film, such as thermal release, UV release, a combination thereof, or other suitable materials, but the present disclosure is not limited thereto. By providing the adhesive layer 11 that may be decomposed by heating or light, the carrier 10 serving as a temporary substrate may be effectively removed in subsequent processes.

As shown in FIG. 1, following the above steps, the cap layer 12 is disposed on the adhesive layer 11, which is used as a carrier in the transfer process. In some embodiments, the material of the cap layer 12 includes a polymer silicon compound. For example, the polymer silicon compound may include polydimethylsiloxane (PDMS), other suitable polymer silicon compounds, or a combination thereof, but the present disclosure is not limited thereto. In some embodiments, the material of the cap layer 12 may be selected according to requirements, so that the cap layer 12 has a specific Young's modulus, viscosity, mechanical strength, chemical resistance, etc. For example, the cap layer 12 may be provided with hardness or chemical resistance that may withstand subsequent photolithography processes and/or etching processes. Alternatively, the cap layer 12 may also have a specific light transmittance so that light emitted by the semiconductor element 13 such as a micro light-emitted diode (uLED) may penetrate. For example, the light transmittance of the cap layer 12 in the visible light wavelength range may be greater than or equal to 95%. For example, the light transmittance of the cap layer 12 in the visible light wavelength range may be 95%, 96%, 97%, 98%, 99%, or any range of the above values.

In some embodiments, the cap layer 12 may be formed on the adhesive layer 11 through the following steps. First, a solution including a catch material may be disposed on the adhesive layer 11. The above-mentioned solution may include the catch material (e.g., dimethylsiloxane), a solvent, a dispersant, other suitable materials, or a combination thereof, but the present disclosure is not limited thereto. Then, the above-mentioned solution may be evenly distributed on the adhesive layer 11 by spinning. In some embodiments, the temperature of the above-mentioned solution may be additionally increased to pre-curing the above solution, but the present disclosure is not limited thereto. Finally, the above-mentioned solution may be cured to form the fully cured or partially cured cap layer 12. The softness and hardness of the cap layer 12 may be controlled by adjusting the curing conditions, such as adjusting the baking temperature, but the present disclosure is not limited thereto. In this way, the cap layer 12 as described above may be obtained. It should be noted that although possible arrangements of the cap layer 12 have been provided above, the present disclosure is not limited thereto. In other embodiments, different arrangement methods or different formation sequences may be used to form the cap layer 12.

As shown in FIG. 1, following the above steps, the semiconductor element 13 is disposed on the cap layer 12, in which the top surface 13A of the semiconductor element 13 faces the cap layer 12. In some embodiments, the semiconductor element 13 may include a light-emitting diode, a laser diode, a photodiode, a photo detector, an integrated circuit (IC), other suitable semiconductor elements, or a combination thereof, but the present disclosure is not limited thereto.

In some embodiments, the semiconductor element 13 may include the semiconductor stack 131 and the plurality of electrodes 132. In some embodiments in which the semiconductor element 13 is a micro light-emitting diode, the semiconductor stack 131 may include a first semiconductor layer, a light-emitting layer, and a second semiconductor layer, which are stacked in sequence. In some embodiments, the first semiconductor layer, the light-emitting layer, and the second semiconductor layer may be formed through an epitaxial growth process, but the present disclosure is not limited thereto. In some embodiments, the first semiconductor layer may be a P-type semiconductor layer, and the second semiconductor layer may be an N-type semiconductor layer. In other embodiments, the conductivity types of the first semiconductor layer and the second semiconductor layer may be interchanged.

In some embodiments, the semiconductor stack 131 may include Group II-VI material or Group III-V material. For example, the Group II-VI material may include zinc selenide (ZnSe). For example, the Group III-V materials may include gallium nitride (GaN), aluminum nitride (AlN), indium arsenide (InP), indium gallium nitride (InGaN), aluminum gallium nitride (AlGaN), aluminum gallium arsenide (AlGaAs), aluminum indium gallium nitride (AlInGaN), aluminum indium gallium phosphide (AlInGaP), the like, or a combination thereof, but the present disclosure is not limited thereto. In some embodiments, the light-emitting layer may include single quantum well (QW) or multiple quantum wells (MQWs). In some embodiments, the P-type semiconductor layer may include a dopant, such as magnesium (Mg) or carbon (C), but the present disclosure is not limited thereto. In some embodiments, the N-type semiconductor layer may include a dopant such as silicon (Si) or germanium (Ge), but the present disclosure is not limited thereto.

In some embodiments, the electrodes 132 are disposed on the side of semiconductor stack 131 opposite the top surface 13A. In some embodiments, the electrodes 132 may include a first electrode and a second electrode electrically connected to the semiconductor stack 131. Specifically, the first electrode may be electrically connected to the first semiconductor layer, and the second electrode may be electrically connected to the second semiconductor layer. In some embodiments, the first electrode and the second electrode may include conductive materials. For example, the conductive material may include metal, conductive compounds, other suitable conductive materials, or a combination thereof, but the present disclosure is not limited thereto. In some embodiments, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), the alloys thereof, or a combination thereof, but the present disclosure is not limited thereto. In some embodiments, the conductive compound may include indium tin oxide (ITO), aluminum zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), titanium nitride (TiN), other suitable conductive compounds, or a combination thereof, but the present disclosure is not limited thereto. In some embodiments, the first electrode and the second electrode may be formed by electroplating, chemical vapor deposition, sputtering, thermal evaporation, electron beam evaporation, atomic layer deposition (ALD), other suitable processes, or a combination thereof, but the present disclosure is not limited thereto.

As shown in FIG. 1, in some embodiments, the step of disposing the semiconductor element 13 on the cap layer 12 further includes the following steps. The carrier 14 with the adhesive layer 15 disposed on is provided first, and the semiconductor element 13 is formed (or disposed) on the adhesive layer 15. Then the adhesive force of the adhesive layer 15 is reduced so that the semiconductor element 13 and a part of the adhesive layer 15 are separated from the carrier 14 and transferred to the cap layer 12. The adhesive layer 15 may be weakened by heating, ultraviolet light irradiation, laser dissociation, other suitable methods, or a combination thereof. However, the present disclosure is not limited thereto. Alternatively, the semiconductor element 13 may also be transferred to the cap layer 12 through a pick-up process. In some embodiments, the carrier 14 may include conductive materials or non-conductive materials. For example, the conductive material may include silicon (Si), silicon carbide (SiC), gallium nitride (GaN), aluminum gallium nitride (AlGaN), aluminum nitride (AlN), gallium phosphide (GaP), gallium arsenide (GaAs), aluminum gallium arsenide (AlGaAs), other suitable materials, or a combination thereof, but the present disclosure is not limited thereto. The non-conductive material may include glass, quartz, sapphire, diamond (C), ceramic, polyimide (PI), polycarbonate (PC), polyethylene terephthalate (PET), polypropylene (PP), other suitable materials, or a combination thereof, but the present disclosure is not limited thereto. In some embodiments, a single semiconductor element 13 may be transferred at a time as shown in FIG. 1, but the present disclosure is not limited thereto. In other embodiments, multiple semiconductor elements 13 may be transferred at a time, such as three, four, five or more semiconductor elements 13 at a time. In some embodiments, the adhesive layer 15 may be a release film, such as thermal release tape, UV release tape, laser release film, a combination thereof, or other suitable materials, but the present disclosure is not limited thereto.

As shown in FIG. 2, in some embodiments in which the semiconductor element 13 is a micro light-emitting diode, three of semiconductor elements 13 may be disposed on the cap layer 12 by, for example, laser release. That is, each packaging structure 1 formed subsequently may include three semiconductor elements 13. It should be noted that the number of semiconductor elements 13 shown in FIG. 2 is only an example, and the present disclosure is not limited thereto. In other embodiments, each packaging structure 1 may include more or less than three semiconductor elements 13, such as one, two, four, or more than four.

In some embodiments, the three semiconductor elements 13 may include a green LED chip, a red LED chip, and a blue LED chip. The green LED chip may emit green visible light with a wavelength between 510 nm and 570 nm, the red LED chip may emit red visible light with a wavelength between 610 nm and 750 nm, and the blue LED chip may emit blue visible light with a wavelength between 440 nm and 470 nm, but the present disclosure is not limited thereto.

In some embodiments, the three semiconductor elements 13 may include multiple LED chips of the same type (for example, emit lights with the same color) and at least two of them are respectively covered by color conversion layers with different colors to convert the colors of the lights of the LED chips, thereby achieving the above-mentioned functions. For example, each of the three semiconductor elements 13 may include the same UV LED chips and include a green conversion layer, a red conversion layer, and a blue conversion layer that are disposed on the UV LED chips. Alternatively, the present disclosure may also use blue LED chips or LED chips of other colors (wavelengths) according to needs, while being not limited to the above-mentioned ultraviolet LED chips. By using the same LED chips, the types of LED chips may be simplified. In some embodiments, each color conversion layer may include materials such as phosphors and quantum dots to convert a single color of light emitted by each LED chip into a specific color of light. For example, an ultraviolet LED chip may combine with a red conversion layer or a green conversion layer including CdSe, so that ultraviolet light may be converted into red visible light or green visible light. For example, an ultraviolet LED chip may combine with a blue conversion layer may including CdS/ZnS, so that ultraviolet light may be converted into blue visible light. The above-mentioned materials and their combinations are only examples, and the present disclosure is not limited thereto.

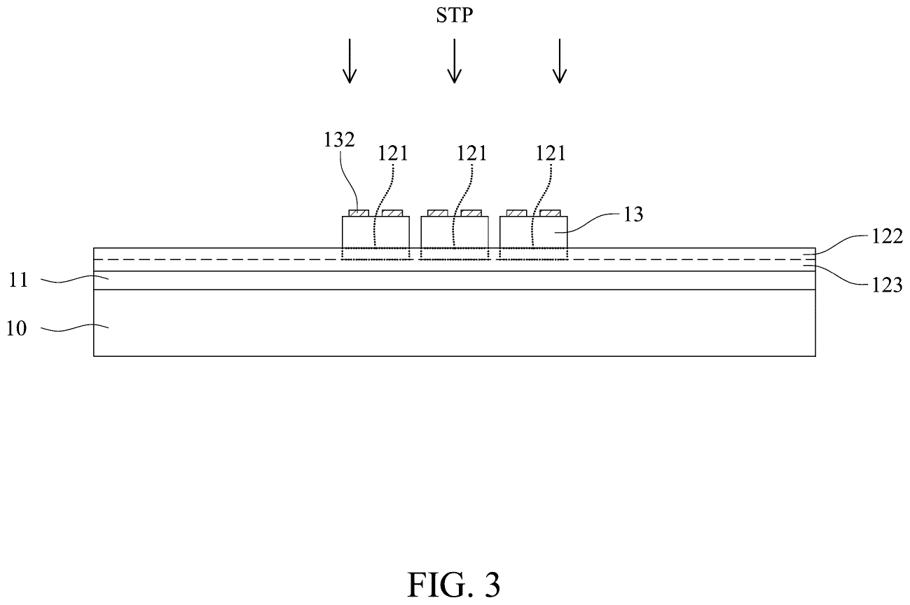

As shown in FIG. 2, the adhesive layer 15′ formed by a process such as laser release may remain on the semiconductor element 13, and the adhesive layer 15′ covers the electrodes 132 of the semiconductor element 13. As shown in FIG. 3, the surface treatment process STP may be performed on the semiconductor element 13 to remove the adhesive layer 15′. After the surface treatment process STP, the remained adhesive layer 15′ is removed from the semiconductor element 13, thereby exposing the electrodes 132 of the semiconductor element 13. In some embodiments, the surface treatment process STP may include inductively coupled plasma clean (ICP clean), other suitable processes, or a combination thereof, but the present disclosure is not limited thereto.

It should be noted that in addition to removing the adhesive layer 15′, the surface treatment process STP, such as inductively coupled plasma clean, may also modify the cap layer 12. Specifically, the cap layer 12 may be divided into a plurality of parts, such as the first part 121, the second part 122, and the third part 123 shown in FIG. 3. In some embodiments, the first part 121 and the second part 122 are located on a side of the cap layer 12 adjacent to the semiconductor element 13, and the third part 123 is located on the side of the cap layer 12 that is placed away from the semiconductor element 13. Specifically, the first part 121 and the second part 122 are arranged side by side on the third part 123, the first part 121 is located between the semiconductor element 13 and the third part 123, and the third part 123 is located between the first part 121 and the carrier 10 and between the second part 122 and the carrier 10. The semiconductor element 13 covers and is in contact with the first part 121 of the cap layer 12 while exposing the second part 122 of the cap layer 12. After the surface treatment process STP, the second part 122 of the cap layer 12 that is not covered by the semiconductor element 13 is modified. On the other hand, the first part 121 of the cap layer 12 is not modified because it is covered by the semiconductor element 13. Similarly, the part of the cap layer 12 that is located away from the semiconductor element 13 (i.e., the third part 123) is not modified.

In some embodiments, the thickness of the first part 121 and the second part 122 in the vertical direction (i.e., the normal direction of the carrier 10) may be between 0.5 μm and 2.5 μm. For example, the thickness of the first part 121 and the second part 122 in the vertical direction may be 0.5 μm, 1 μm, 1.5 μm, 2 μm, 2.5 μm, or any value or range between the above values, but the present disclosure is not limited thereto. In some embodiments, the thickness of the third part 123 in the vertical direction may be between 5 μm and 150 μm. For example, the thickness of the third part 123 in the vertical direction may be 5 μm, 10 μm, 15 μm, 40 μm, 60 μm, 80 μm, 100 μm, 125 μm, 150 μm, or any value or range between the above values, but the present disclosure is not limited thereto.

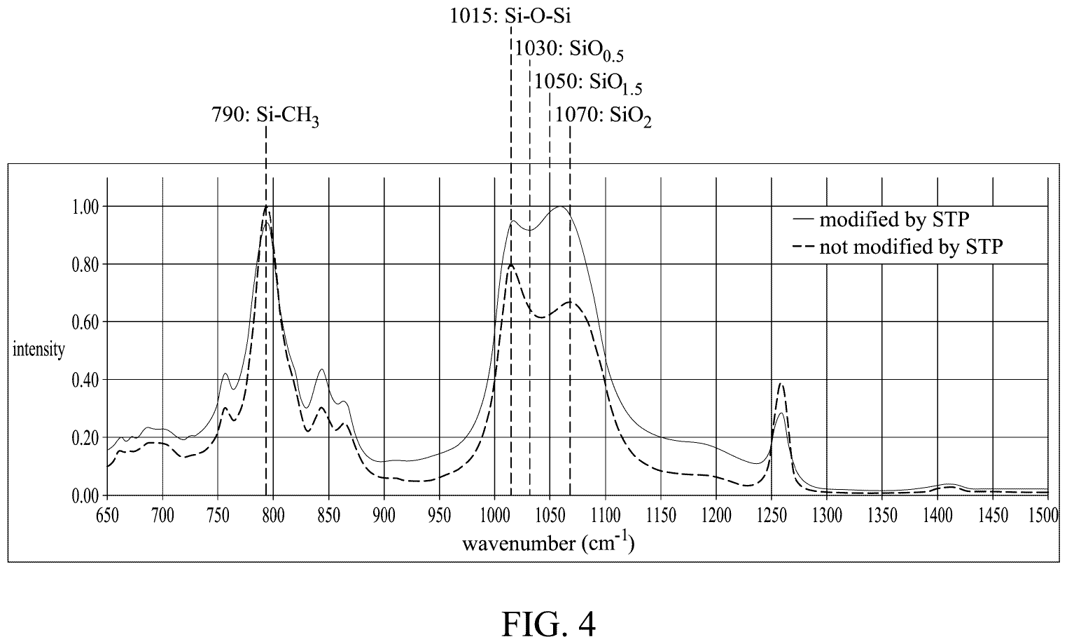

FIG. 4 is a measurement result shown a Fourier transform infrared spectra of different parts of the cap layer 12 according to some embodiments of the present disclosure. As shown in FIG. 4, after the surface treatment process STP such as inductively coupled plasma clean, the material structure of the cap layer 12 is partially modified and changed. Specifically, after the surface treatment process STP is performed, the characteristic peaks of the network structure of SiO₂ (located at the wavenumber of 1070 cm⁻¹) of the part of the cap layer 12 that has been modified by the surface treatment process STP (such as the second part 122) becomes more obvious than that of the parts of the cap layer 12 that have not undergone the surface treatment process STP and have not been modified (such as the first part 121 and the third part 123). It indicates that the ratio of the SiO₂ with a network-like structure is increased, which may make the surface of the cap layer 12 (for example, the modified second part 122) more dense, thereby improving the effect of resisting peeling.

In some embodiments, in the measurement results of Fourier transform infrared spectroscopy, the ratio between the maximum intensity of the second part 122 at the wavenumber of 1060 cm⁻¹ to the wavenumber of 1080 cm⁻¹ (representing the characteristic peak of SiO₂ with the network structure) and the maximum intensity of the second part 122 at the wavenumber of 780 cm⁻¹ to the wavenumber of 800 cm⁻¹ (representing the characteristic peak of Si—CH₃) is greater than 0.65. For example, the ratio between the maximum intensities may be 0.65, 0.675, 0.7, 0.725, 0.75, 0.775, 0.8, 0.825, 0.85, or any value or range between the above values, but the present disclosure is not limited thereto. On the contrary, in some embodiments, in the measurement results of Fourier transform infrared spectroscopy, the ratio between the maximum intensity of the first part 121 or the third part 123 at the wavenumber of 1060 cm⁻¹ to the wavenumber of 1080 cm⁻¹ (representing the characteristic peak of SiO₂ with the network structure) and the maximum intensity of the first part 121 or the third part 123 at the wavenumber of 780 cm⁻¹ to the wavenumber of 800 cm⁻¹ (representing the characteristic peak of Si—CH₃) is less than 0.65. For example, the ratio between the maximum intensities may be 0.65, 0.625, 0.6, 0.575, 0.55, 0.525, 0.5, 0.475, 0.45, or any value or range between the above values, but the present disclosure is not limited thereto.

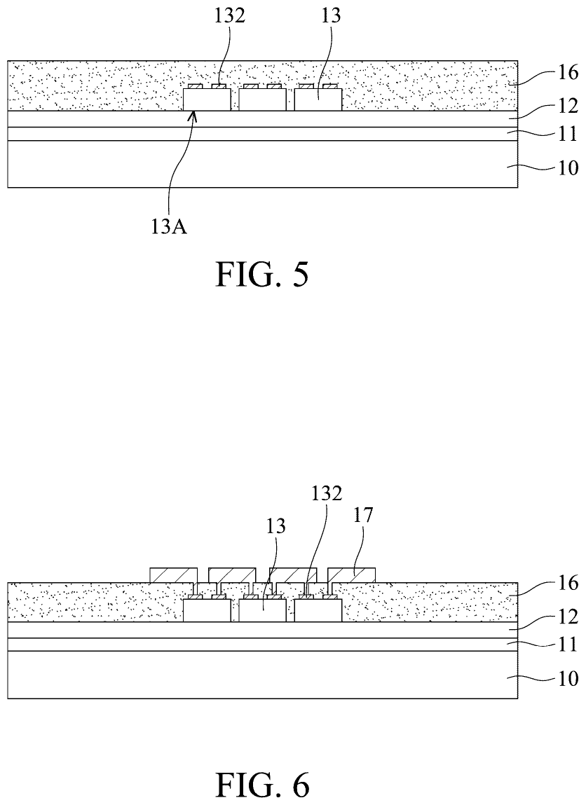

As shown in FIG. 5, the wrap layer 16 may be disposed on the semiconductor element 13 and the cap layer 12. Specifically, the wrap layer 16 covers and is in contact with the semiconductor element 13 and the second part 122 of the cap layer 12. In some embodiments, the wrap layer 16 may be or may include epoxy, polyimide (PI), polybenzoxazole (PBO), silicone resin, silicon dioxide, silicon nitride, nitride, or a combination thereof, but the present disclosure is not limited thereto.

In some embodiments, the wrap layer 16 covers the side surfaces and the electrodes 132 of the semiconductor element 13 but is not in contact with the top surface 13A of the semiconductor element 13. In some embodiments where the top surface 13A of the semiconductor element 13 is used as a light emission surface, the transmittance of the wrap layer 16 in the visible wavelength range is less than 5% to make the light emitted by the light-emitting layer of the semiconductor element 13 concentrated towards the top surface 13A, thereby avoiding crosstalk between adjacent semiconductor elements 13. For example, the transmittance of the wrap layer 16 in the visible light wavelength range may be 5%, 4%, 3%, 2%, 1%, or any range of the above values. In some embodiments, the wrap layer 16 may include a material with light reflectivity greater than 90% to adjust the light transmittance of the wrap layer 16. For example, black dispersed particles such as carbon black may be added to the wrap layer 16 so that the light transmittance of the wrap layer 16 is less than 5%, so that the wrap layer 16 appears black.

As shown in FIG. 6, the connecting portion 17 is disposed on the wrap layer 16, in which the connecting portion 17 extends through the wrap layer 16 and is electrically connected to the electrodes 132 of the semiconductor element 13. Specifically, a part of the wrap layer 16 may be removed first to expose the electrodes 132 of the semiconductor element 13, and then the connecting portion 17 may be formed on the exposed electrodes 132 and the wrap layer 16. In some embodiments, the connecting portion 17 may include conductive material. For example, the conductive material may include metal, conductive compounds, other suitable conductive materials, or a combination thereof, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or alloys thereof. For example, the conductive compound may be tantalum nitride (TaN), titanium nitride (TiN), tungsten silicon oxide (WSi₂), indium tin oxide (ITO), etc. In some embodiments, a part of the wrap layer 16 may be removed through a photolithography process, and the connecting portion 17 may be formed through an electroplating process, a sputtering process, or an evaporation process, but the present disclosure is not limited thereto.

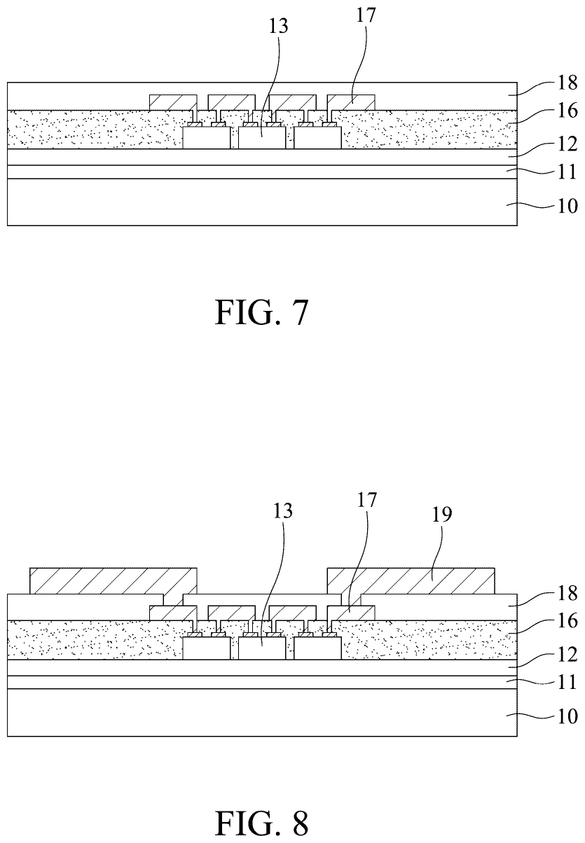

As shown in FIG. 7, the base 18 may be disposed on the wrap layer 16 and the connecting portion 17. Specifically, the base 18 covers the wrap layer 16 and the connecting portion 17. In some embodiments, the base 18 may include epoxy, polyimide (PI), polybenzoxazole (PBO), silicone resin, silicon oxide, silicon nitride, or a combination thereof, but the present disclosure is not limited thereto.

As shown in FIG. 8, the bonding pad 19 may be disposed on the base 18, in which the bonding pad 19 extends through the base 18 and is electrically connected to the semiconductor element 13 through the connecting portion 17. Specifically, a part of the base 18 may be removed first to expose a part of the connecting portion 17, and then the bonding pad 19 may be formed on the exposed connecting portion 17 and the base 18. In some embodiments, the bonding pad 19 may include conductive material. For example, the conductive material may include metal, conductive compounds, other suitable conductive materials, or a combination thereof, but the present disclosure is not limited thereto. In some embodiments, the material of the bonding pad 19 may be similar or the same as the material of the connecting portion 17, but the present disclosure is not limited thereto. In some embodiments, a part of the base 18 may be removed by a photolithography process, and the bonding pad 19 may be formed by a plating process, a sputtering process, or an evaporation process, but the present disclosure is not limited thereto. In some embodiments, the bonding pad 19 and the connecting portion 17 may be collectively referred to as an electrical connecting structure or a redistribution structure, which penetrate the base 18 and the wrap layer 16 to electrically connect to the semiconductor element 13.

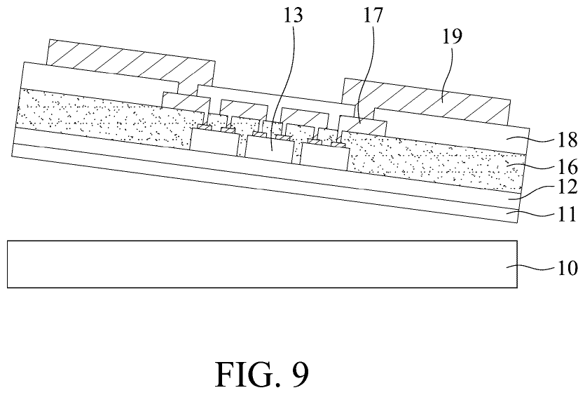

As shown in FIG. 9, the carrier 10 may be removed. For example, the carrier 10 may be removed through a laser lift-off process, other suitable processes, or a combination thereof, but the present disclosure is not limited thereto.

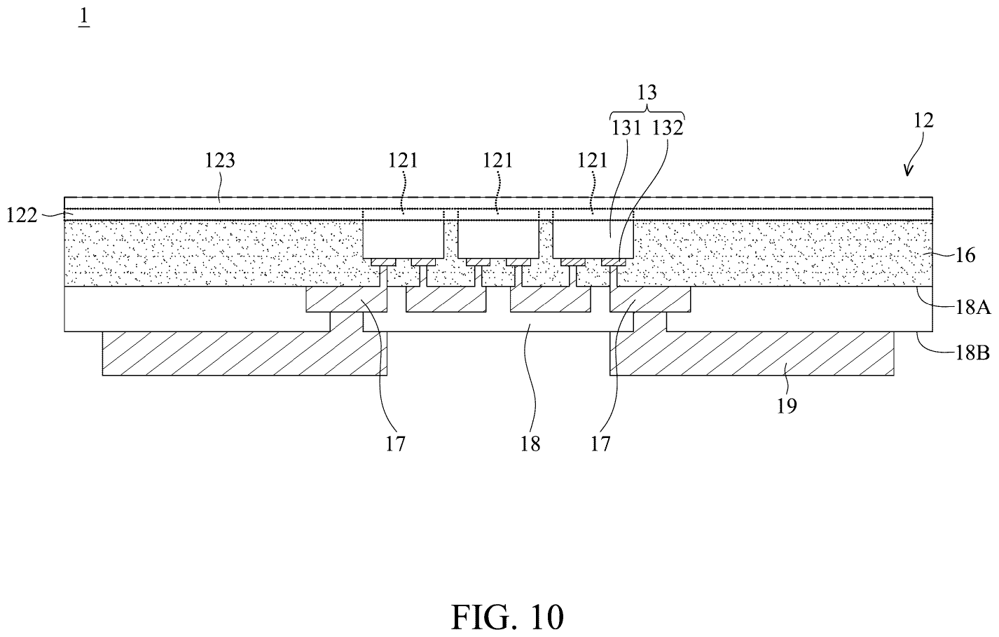

As shown in FIG. 10, the structure obtained by the above steps is turned over (flipped) and the adhesive layer 11 is removed to obtain the packaging structure 1. For example, the adhesive layer 11 may be removed through an etching process, a heating process, an illumination process, other suitable processes, or a combination thereof, but the present disclosure is not limited thereto.

In some embodiments, the carrier 10 and the adhesive layer 11 may be removed simultaneously in the same process by removing the adhesive layer 11 between the carrier 10 and the cap layer 12. It should be noted that the above manners are only examples, and the present disclosure is not limited thereto. In some other embodiments, the adhesive layer 11 or a part of the carrier 10 may also be directly removed by physical destruction to separate it from the cap layer 12.

It should be noted that, although not shown in the drawings, in some embodiments, multiple packaging structures 1 may be formed simultaneously through the above steps. Therefore, before or after the process of removing the adhesive layer 11, a dicing process may be performed to separate multiple packaging structures 1 from each other and form a single packaging structure 1 as shown in FIG. 10.

In summary, in the present disclosure, by retaining the cap layer 12 as a carrier in the transfer process, the molding step, the flipping step, and the debonding step may be omitted after the element is transferred. In this way, the packaging structure 1 of the present disclosure may greatly simplify the manufacturing process, so as to have the benefit effects of fewer formation steps and lower cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A packaging structure, comprising:
a base having a first side and a second side opposite to each other;
a semiconductor element disposed on the first side of the base;
a wrap layer disposed on the first side of the base, wherein the wrap layer covers the semiconductor element and exposes a top surface of the semiconductor element;
a cap layer disposed on the wrap layer and the semiconductor element and comprising:
a first part covering and in contact with the top surface of the semiconductor element; and
a second part covering and in contact with the wrap layer, wherein in measurement results of Fourier transform infrared spectroscopy, a ratio between a maximum intensity of the second part at a wavenumber of 1060 cm⁻¹ to a wavenumber of 1080 cm⁻¹ and a maximum intensity of the second part at a wavenumber of 780 cm⁻¹ to a wavenumber of 800 cm⁻¹ is greater than 0.65; and
an electrical connecting structure disposed on the second side of the base and passing through the base and the wrap layer to electrically connect to the semiconductor element.

2. The packaging structure as claimed in claim 1, wherein in the measurement results of Fourier transform infrared spectroscopy, a ratio between a maximum intensity of the first part at a wavenumber of 1060 cm⁻¹ to a wavenumber of 1080 cm⁻¹ and a maximum intensity of the first part at a wavenumber of 780 cm⁻¹ to a wavenumber of 800 cm⁻¹ is less than 0.65.

3. The packaging structure as claimed in claim 1, wherein a thickness of the first part or the second part in a vertical direction is between 0.5 μm and 2.5 μm.

4. The packaging structure as claimed in claim 1, wherein the cap layer further comprises a third part, and the third part is disposed on the first part and the second part, wherein in the measurement results of Fourier transform infrared spectroscopy, a ratio between a maximum intensity of the third part at a wavenumber of 1060 cm⁻¹ to a wavenumber of 1080 cm⁻¹ and a maximum intensity of the third part at a wavenumber of 780 cm⁻¹ to a wavenumber of 800 cm⁻¹ is less than 0.65.

5. The packaging structure as claimed in claim 4, wherein a thickness of the third part in a vertical direction is between 5 μm and 150 μm.

6. The packaging structure as claimed in claim 1, wherein a material of the cap layer comprises a polymer silicon compound.

7. The packaging structure as claimed in claim 6, wherein the polymer silicon compound comprises polydimethylsiloxane (PDMS).

8. The packaging structure as claimed in claim 1, wherein a light transmittance of the wrap layer in a visible light wavelength range is less than 5%, and a light transmittance of the cap layer in the visible light wavelength range is greater than or equal to 95%.

9. The packaging structure as claimed in claim 1, wherein the wrap layer comprises at least one of epoxy, polyimide (PI), polybenzoxazole (PBO), silicone resin, silicon dioxide, and silicon nitride.

10. The packaging structure as claimed in claim 1, wherein the electrical connecting structure comprises a connecting portion and a bonding pad, the bonding pad is on the second side of the base, and the semiconductor element is electrically connected to the bonding pad through the connecting portion.

11. A formation method of a packaging structure, comprising:
providing a cap layer;
disposing a semiconductor element on the cap layer, wherein a top surface of the semiconductor element covers a portion of the cap layer;
performing a surface treatment process on the semiconductor element and a portion of the cap layer not covered by the semiconductor element;
disposing a wrap layer on the semiconductor element and the cap layer;
disposing a connecting portion on the wrap layer, wherein the connecting portion is electrically connected to the semiconductor element;
disposing a base on the wrap layer; and
disposing a bonding pad on the base, wherein the bonding pad is electrically connected to the connecting portion.

12. The formation method of the packaging structure as claimed in claim 11, wherein the step of disposing the semiconductor element on the cap layer further comprises:
disposing a carrier;
disposing an adhesive layer on the carrier;
disposing the semiconductor element on the adhesive layer; and
transferring the semiconductor element and the adhesive layer to the cap layer.

13. The formation method of the packaging structure as claimed in claim 12, wherein the surface treatment process removes the adhesive layer on the semiconductor element.

14. The formation method of the packaging structure as claimed in claim 11, wherein the surface treatment process comprises inductively coupled plasma clean (ICP clean).

15. The formation method of the packaging structure as claimed in claim 11, wherein in the step of performing the surface treatment process, the surface treatment process is not performed on the portion of the cap layer covered by the semiconductor element.

16. The formation method of the packaging structure as claimed in claim 15, wherein after performing the surface treatment process, the cap layer comprises:
a first part covered by the semiconductor element; and
a second part not covered by the semiconductor element, wherein in measurement results of Fourier transform infrared spectroscopy, a ratio between a maximum intensity of the second part at a wavenumber of 1060 cm⁻¹ to a wavenumber of 1080 cm⁻¹ and a maximum intensity of the second part at a wavenumber of 780 cm⁻¹ to a wavenumber of 800 cm⁻¹ is greater than 0.65.

17. The formation method of the packaging structure as claimed in claim 16, wherein in the measurement results of Fourier transform infrared spectroscopy, a ratio between a maximum intensity of the first part at a wavenumber of 1060 cm⁻¹ to a wavenumber of 1080 cm⁻¹ and a maximum intensity of the first part at a wavenumber of 780 cm⁻¹ to a wavenumber of 800 cm⁻¹ is less than 0.65.

18. The formation method of the packaging structure as claimed in claim 16, wherein a thickness of the first part or the second part in a vertical direction is between 0.5 μm and 2.5 μm.

19. The formation method of the packaging structure as claimed in claim 16, wherein the cap layer further comprises a third part, and the third part is on sides of the first part and the second part away from the semiconductor element, wherein in the measurement results of Fourier transform infrared spectroscopy, a ratio between a maximum intensity of the third part at a wavenumber of 1060 cm⁻¹ to a wavenumber of 1080 cm⁻¹ and a maximum intensity of the third part at a wavenumber of 780 cm⁻¹ to a wavenumber of 800 cm⁻¹ is less than 0.65.

20. The formation method of the packaging structure as claimed in claim 19, wherein a thickness of the third part in a vertical direction is between 5 μm and 150 μm.
